(19) United States
(12) Patent Application Publication
(10) Pub. No.: US 2020/0035847 A1
(43) Pub. Date: Jan. 30, 2020

(54) SOLAR CELL MODULE

(71) Applicant: KANEKA CORPORATION, Osaka (JP)

(72) Inventors: Toru Terashita, Osaka (JP); Daisuke Adachi, Osaka (JP); Takashi Suezaki, Osaka (JP); Hitoshi Tamai, Osaka (JP)

(73) Assignee: KANEKA CORPORATION, Osaka (JP)

(21) Appl. No.: 16/587,454

(22) Filed: Sep. 30, 2019

Related U.S. Application Data
(63) Continuation of application No. PCT/JP2018/013465, filed on Mar. 29, 2018.

(30) Foreign Application Priority Data
Mar. 30, 2017 (JP) 2017-067240

(51) Int. Cl. H01L 31/05; H01L 31/049

(52) U.S. Cl. CPC H01L 31/0508; H01L 31/049

(57) ABSTRACT

A solar cell module includes a solar cell string in which a first solar cell and a second solar cell are arranged apart from each other along a first direction. The first and second solar cells are connected by a strip-shaped wiring member, and the solar cell string is arranged between a light-receiving-surface protection member and a back-surface protection member. The wiring member has, along the first direction, an uneven region where the first principal surface is provided with unevenness, and a flat region where the first principal surface is not provided with unevenness or is provided with unevenness that is smaller in height than the uneven region. The uneven region extends from the light-receiving surface of the second solar cell to the back surface of the first solar cell.

### TECHNICAL FIELD

One or more embodiments of the invention relate to a solar cell module.

### BACKGROUND

Solar cells that include crystalline semiconductor substrates such as a single-crystalline silicon substrate and a polycrystalline silicon substrate have a small area for one substrate, and thus in practical use, a plurality of solar cells are electrically connected through wiring members and modularized for increasing output. No light enters the regions provided with wiring members at the light-receiving surfaces of the solar cells, thus causing shadowing loss. A method is known in which, by using a light-diffusion wiring member with uneven structure on the light-receiving side, irradiation light is reflected at the inclined surface of the unevenness in various directions to make the light on solar cells, thereby improving the light utilizing efficiency.

In connection of the light-receiving surface (uneven formed surface) of the light-diffusion wiring member on a back electrode of the solar cell, because of the small area of contact between the uneven formed surface and the electrode, insufficient connection may cause an electrical loss due to an increase in resistance, or decreased reliability. Patent Document 1 and Patent Document 2 propose wiring members configured such that the region connected to the light-receiving surface of a solar cell is provided with surface unevenness, whereas the region connected to the back surface of the solar cell is not provided with surface unevenness. In such a wiring member, both a surface connected to a light-receiving electrode of the solar cell and a surface connected to a back electrode of the solar cell are formed in a flat surface, thus the wiring member and the solar cell are stably connected with a solder or the like.

### PATENT DOCUMENTS

Patent Document 1: JP 2012-9681 A
Patent Document 2: WO 2007/067304 A

### SUMMARY

One or more embodiments of the present invention provide a solar cell module capable of achieving a balance between light utilizing efficiency and long-term reliability.

The solar cell module includes a solar cell string, a light-transmitting light-receiving-surface protection member disposed on the light-receiving side, a back-surface protection member disposed on the back side, and an encapsulant that encapsulates the solar cell string between the light-receiving-surface protection member and the back-surface protection member. For the solar cell string, a first solar cell and a second solar cell arranged apart from each other are connected by a strip-shaped wiring member.

The wiring member has a first principal surface connected to an electrode arranged on a back surface of the first solar cell, and a second principal surface connected to an electrode arranged on a light-receiving surface of the second solar cell. The wiring member has, along an extending direction, an uneven region where the first principal surface is provided with unevenness, and a flat region where the first principal surface is not provided with unevenness or is provided with unevenness that is smaller in height than the uneven region. The uneven region is arranged so as to extend from the light-receiving surface of the second solar cell to the back surface of the first solar cell.

In the solar cell module according to one or more embodiments of the present invention, the first principal surface of the wiring member is provided with unevenness, and the solar cell module is thus excellent in light utilizing efficiency. The part of the wiring member disposed on the back surface of the solar cell has both the flat region and the uneven region, and the flat region can improve the reliability of the electrical connection between the solar cell and the wiring member. The encapsulant filling the gap between the unevenness of the wiring member disposed on the back surface of the solar cell and the solar cell contributes to adhesiveness and cushioning action, thereby making it possible to improve the reliability of the solar cell module.

### BRIEF DESCRIPTION OF THE DRAWINGS

FIG. 1 is a schematic cross-sectional view, in a cell connection direction, of a solar cell module according to one or more embodiments.

FIG. 2A is a plan view of the light-receiving side of a solar cell string according to one or more embodiments.

FIG. 2B is a plan view of the back side of a solar cell string according to one or more embodiments.

FIG. 3A is a cross-sectional view of a solar cell module in a direction perpendicular to the cell connection direction according to one or more embodiments.

FIG. 3B is a cross-sectional view of a solar cell module in a direction perpendicular to the cell connection direction according to one or more embodiments.

FIG. 4 is a schematic perspective view of a wiring member according to one or more embodiments.

FIG. 5 is a schematic perspective view of a wiring member before cutting.

### DETAILED DESCRIPTION OF THE EMBODIMENTS

FIG. 1 is a schematic sectional view of a solar cell module (hereinafter referred to as a “module”) according to one or more embodiments. The module 200 includes a plurality of solar cells 101, 102, 103, and 104 (hereinafter referred to as “cells”) arranged along the x direction, and the respective cells are arranged apart from each other. Each of the cells includes electrodes 60 and 70 respectively on the light-receiving surface and back surface of a photoelectric conversion section 50. As for adjacent cells, the light-receiving electrode 60 of one cell and the back electrode 70 of the other cell are connected by strip-shaped wiring members 81, 82, and 83 extending along the x direction. In this way, a plurality of cells are connected via wiring members to form a solar cell string.

A light-receiving-surface protection member 91 with light transmissivity is disposed on the light-receiving side (the upper side in FIG. 1) of the solar cell string, and a back-surface protection member 92 is disposed on the back side (the lower side in FIG. 1) of the solar cell string. In the module 200, the solar cell string is encapsulated by filling the space between the protection members 91 and 92 with an encapsulant 95.

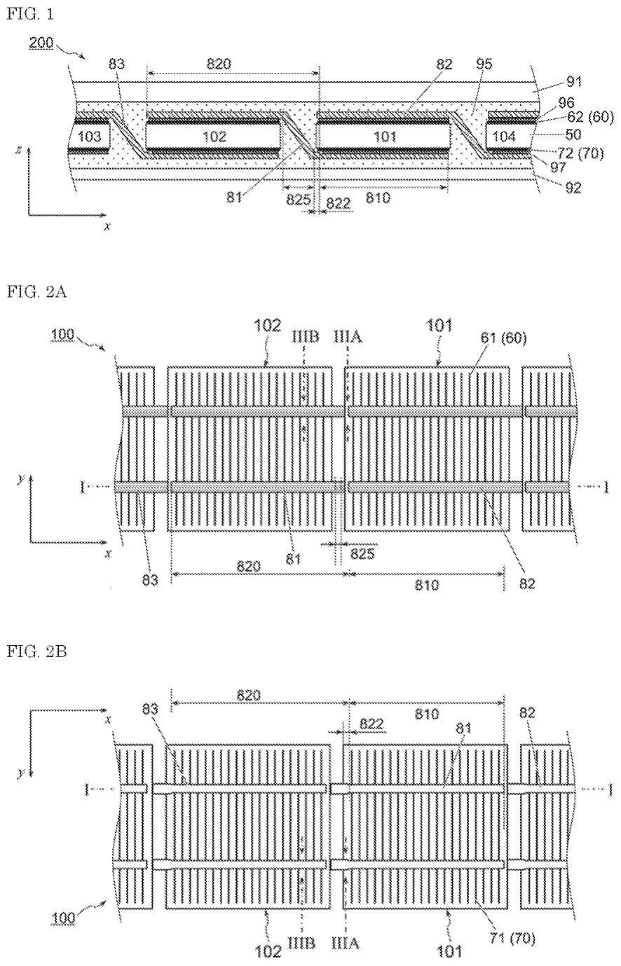

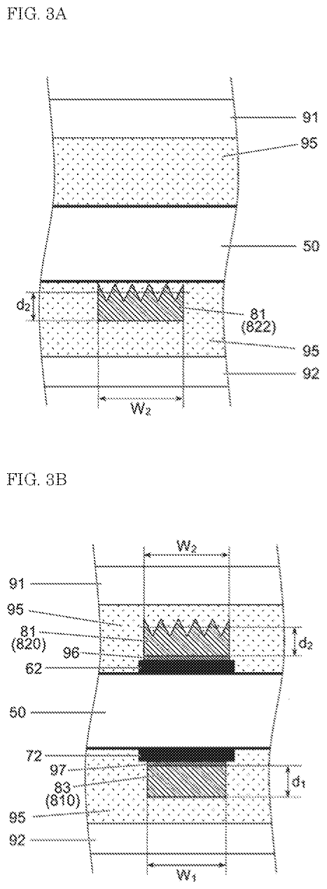

FIG. 2A is a plan view of the light-receiving side of a solar cell string according to one or more embodiments, and FIG. 2B is a plan view of the back side of a solar cell string according to one or more embodiments. FIG. 1 corresponds to the cross section taken along the line I-I of FIGS. 2A and 2B. FIG. 3A is a cross-sectional view (along the line IIIA line in FIGS. 2A and 2B) of an end of the first cell 101 in the x direction, and FIG. 3B is a cross-sectional view (along the IIIB line in FIGS. 2A and 2B) of a central part of the second cell 102 in the x direction.

In one or more embodiments, as the cell, a type of solar cells that are configured to be interconnected with a wiring member can be used, such as a crystalline silicon solar cell or a solar cell including a semiconductor substrate other than silicon such as GaAs. In one or more embodiments, irregularities on the order of about 1 to 10 μm in height may be formed on the light-receiving surface of the photoelectric conversion section 50 of the cell. Optical confinement efficiency can be enhanced and reflectance can be reduced by forming irregularities on the light-receiving surface,

In one or more embodiments, the light-receiving electrode 60 disposed on the light-receiving surface of the photoelectric conversion section 50 has a specific pattern shape, and light can be captured from a section where no electrode is disposed. The pattern shape of the light-receiving electrode 60 is not particularly limited. As shown in FIG. 2A, the light-receiving electrode 60 may be formed in, for example, a grid shape consisting of a plurality of finger electrodes 61 extending in y direction and bus bar electrodes 62 extending in x direction and perpendicular to the finger electrodes. The back electrode 70 may have a pattern shape like the light-receiving electrode, or may be disposed over the entire surface on the photoelectric conversion section. In FIG. 2B, as with the light-receiving electrode, the back electrode has a grid shape consisting of finger electrodes 71 and bus bar electrodes 72. In FIGS. 2A and 2B, the wiring members are disposed on the bus bar electrodes, and therefore the bus bar electrodes are not shown.

In one or more embodiments, the wiring member 81 has a first principal surface disposed to face the light receiving side and a second principal surface disposed to face the back side. In the solar cell string 100, the first principal surface of the wiring member 81 is connected to the back electrode 70 of the first cell 101, and the second principal surface of the wiring member 81 is connected to the light-receiving electrode 60 of the second cell 102.

In one or more embodiments, adhesive materials 96, 97 for bonding the electrodes 60, 70 formed on the cell and the wiring member 81 are disposed therebetween. As the adhesive material, a solder, a conductive adhesive, a conductive film, or the like is used. In the solar cell string 100, the wiring members are flat at both of the surface connected to the light-receiving electrode 60 and the surface connected to the back electrode 70, and there is thus a tendency that adhesion strength and adhesion reliability are improved in a case where a solder is used as the adhesive materials 96 and 97.

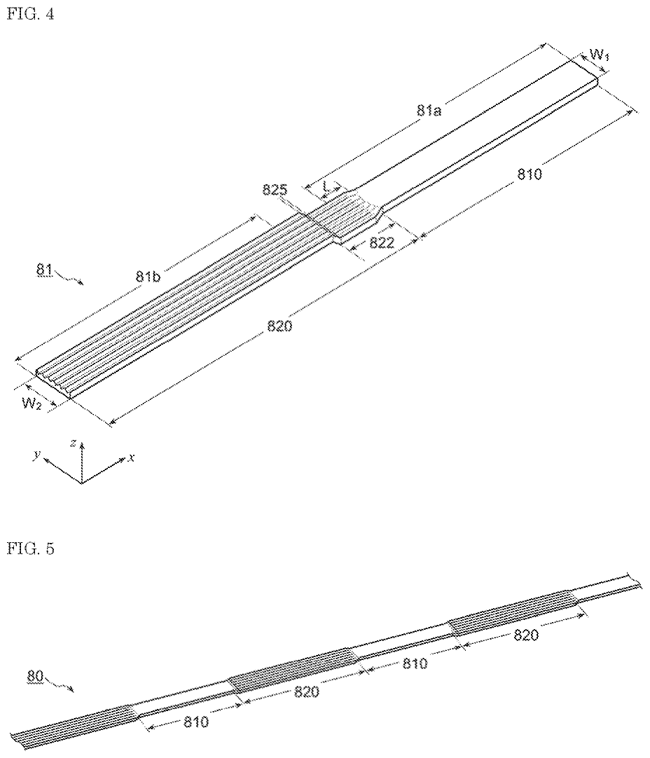

FIG. 4 is a schematic perspective view of the wiring member before connection to the cell according to one or more embodiments. The wiring member 81 has a flat region 810 and an uneven region 820 along the extending direction (x direction). In the uneven region 820, the first principal surface is provided with unevenness. The flat region 810 has smaller unevenness height on the first principal surface than the uneven region 820. In one or more embodiments, the flat region 810 may not be provided with unevenness.

The length of the wiring member 81 along the x direction is approximately twice the length of one side of the cell along the x direction in one or more embodiments. In the module, as shown in FIG. 1, the wiring member 81 is disposed to extend from the vicinity of one side (+x side) of the first cell to the vicinity of the other (−x side) end of the second cell. For the wiring member 81, the length of the uneven region 820 along the x direction is larger than the length of the flat region 810 along the x direction. The wiring member 81 has, in the center along the x direction, a bent part 825 in which the wiring member is inclined downward (−z side) from the −x side toward the +x side. In the solar cell string 100, the bent part 825 is arranged in the gap between the two adjacent cells 101 and 102. With the bent part 825 as a boundary, the region 81a on the +x side is a region disposed on the back surface of the first cell 101, whereas the region 81b on the −x side is a region disposed on the light-receiving surface of the second cell 102.

In one or more embodiments, the entire region 81b disposed on the light-receiving surface of the second cell 102 of the wiring member 81 is encompassed in the uneven region 820. The uneven region 820 further extends over the bent part 825, and also a region 822 on the +x side from the bent part 825. Along the x direction, most part of the region 81a disposed on the back surface of the first cell 101 is the flat region 810, but the end of the region 81a on the side (−x side) closer to the bent part 825 overlaps with the uneven region 822. In one or more embodiments, in the solar cell string 100, the uneven region 820 of the wiring member 81 is arranged so as to extend from the light-receiving surface of the second cell 102 to the back surface of the first cell 101.

In one or more embodiments, the region 81b and bent part 825 disposed on the light-receiving surface of the cell are entirely included in the uneven region 820, and thus, as shown in FIG. 2A, in the solar cell string 100, the first principal surface of the wiring member visually confirmed from the light receiving side serves as an uneven over the entire region.

In one or more embodiments, the first principal surface of the wiring member is provided with unevenness, thereby scattering and reflecting light irradiation from the light-receiving side to the wiring member at the unevenness of the surface. The light scattered and reflected by the uneven region 820 of the wiring member is reflected again by the light-receiving-surface protection member 91, and capable of entering the cell from the region where the wiring member is not disposed, thereby allowing the light utilizing efficiency of the module to be improved. In the solar cell string 100, the first principal surface of the wiring member is provided with unevenness over the entire region of the gap between the adjacent cells, thus allowing light irradiation to the wiring member disposed in the gap between the cells to also enter the cells by scattering and reflecting the light, and allowing the light utilizing efficiency of the module to be further improved.

The material of the wiring member may have low resistance in one or more embodiments. Materials containing copper as main constituent may be used because of its low cost. In order to increase the amount of light reflected by the uneven structure at the surface of the wiring member, the surface of the first principal surface of the uneven region 820 may be coated with a highly light reflective material such as gold, silver, copper, or aluminum. In some embodiments, a metal layer containing silver as a main constituent may be formed.

The uneven structure in the uneven region 820 of the wiring member is not particularly limited as long as the uneven structure is capable of scattering and reflecting light, and may have a regular shape or an irregular shape. Examples of the uneven shape include pyramidal shapes such as square pyramidal shape and inverted square pyramidal shape, and columnar shapes such as triangular prismatic shapes and semicircular columnar shapes. In one or more embodiments, because light irradiation to the wiring member can be scattered and reflected at a large angle, a columnar shape that extends in parallel to the first principal surface may be selected, and in a cross section perpendicular to the extending direction, the cross sectional shape of the columnar may be a triangle. In one or more embodiments, the uneven region 820 may have a triangular prism-shaped projected part or the uneven region 820 may have a plurality of triangular prism-shaped projected parts arranged in parallel. In a case where the cross-sectional shape of the projected part is triangle, the elevation angle of the slope of the projected part may be 20 to 70°. Although the height of the projected part is not particularly limited, the height may be 5 to 100 μm or 10 to 80 μm.

The width of the wiring member can be appropriately selected depending on the electrode configuration of the cell (for example, the width and number of bus bar electrodes), and may be about 0.5 to 3 mm in one or more embodiments. Typically, the width of the wiring member is set to about the same as the width of the bus bar electrode. In a case where a small-width bus bar (thin-wire bus bar) is disposed on the cell surface, the width of the wiring member may be made larger than the width of the bus bar electrode. As described later, for the wiring member, the width W₁ of the flat region 810 and the width W₂ of the uneven region 820 may be different from each other.

Although the wiring member 81 with the projected part extending parallel to the extending direction (x direction) is shown in FIG. 4, the extending direction of the projected part is not particularly limited. The extending direction of the projected part may have a predetermined angle with the x direction, and the projected part may extend in a direction (y direction) perpendicular to the x direction. When the projected part extends non-parallel to the extending direction of the wiring member, light from various angles (azimuth and altitude) can be scattered and reflected, and the light reflected again by the light-receiving-surface protection member can be taken into the cell.

As shown in FIG. 3B, the second principal surface of the wiring member is not provided with unevenness in one or more embodiments. Thus, the area of contact between the light-receiving-surface bus bar electrode 62 of the cell and the wiring member 81 is increased, thereby making it possible to improve the adhesion strength and adhesion reliability between the electrode and the wiring member. In addition, it is possible to connect the electrode and the wiring member with the use of a solder as the adhesive material 96, thus making it possible to improve the adhesion strength and the adhesion reliability and reduce the material cost. In the case of using a solder as the adhesive material 96, the wiring member 81 may be used with the second principal surface of the region 81b coated with the solder. The bent part 825 and region 81a of the wiring member 81 may also have second principal surfaces coated with the solder.

As viewed along the x direction, most part of the region 81a of the wiring member 81, which is arranged on the back side of the first cell, is flat region 810 in one or more embodiments. Thus, the contact area between the back-surface bus bar electrode 72 of the cell and the wiring member 81 is increased, thereby making it possible to improve the adhesion strength and adhesion reliability between the electrode and the wiring member. In addition, as with the connection to the light-receiving-surface bus bar electrode 62, it is possible to use a solder as the adhesive material 97 for the connection between the back-surface bus bar electrode 72 and the wiring member 81. As just described, the first principal surface is provided with unevenness in the region 81b where the wiring member 81 is disposed on the light-receiving surface of the cell, whereas the first principal surface is formed to be a flat part in the region 81a where the wiring member 81 is disposed on the back surface. Accordingly, the improved light utilizing efficiency by scattering and reflection and the improved adhesion strength and adhesion reliability with the cell can be made compatible.

In one or more embodiments, the uneven region 820 of the wiring member 81 also extends over the region 822 on the +x side from the bent part 825, and the region 822 overlaps with the region 81a disposed on the back surface of the first cell 101. Thus, at the end of the first cell 101, as shown in FIG. 3A, the first principal surface of the wiring member 81 provided with unevenness faces the back surface of the cell.

In one or more embodiments, no bus bar electrode is disposed in the vicinity of the end edge of the cell, and thus, the back surface bus bar electrode is not disposed in the part where the uneven region 822 of the wiring member 81 and the back surface of the cell face each other. The wiring member 81 and the back-surface bus bar electrode 72 may be connected or may not be connected in the part where the uneven region 822 of the wiring member 81 and the back-surface bus bar electrode 72 of the cell face each other. The proportion of the uneven region 822 is low with respect to the entire region 81a of the wiring member 81 disposed on the back side of the first cell. Since the flat region 810 of wiring member 81 is connected to the back surface bus bar electrode with the adhesive material 97 such as a solder interposed therebetween, the electrical connection between the back-surface bus bar electrode 72 and wiring member 81 can be sufficiently secured, even if the region 822 is not connected to the back surface bus bar electrode.

In one or more embodiments, in the module 200, the solar cell string 100 is encapsulated between the light-receiving-surface protection member 91 and the back-surface protection member 92, and thus, as shown in FIG. 3A, the recessed part of the unevenness provided in the region 822 of the wiring member 81 is filled with an encapsulant 95. Since the first principal surface of the wiring member 81 has unevenness in the region extending from the gap between the first cell 101 and the adjacent second cell 102 to the back surface of the first cell 101, the encapsulant is likely to get around the uneven region 822. The encapsulant has a cushioning action, thus making it possible to suppress mechanical damage such as a scratch or crack on the back surface of the cell due to the unevenness of the wiring member. In addition, since the surface is provided with unevenness, the first principal surface of the uneven region 822 has a larger area of bonding to the encapsulant, as compared with the flat region. Thus, it is possible to secure the adhesion to the back surface of the cell with the encapsulant interposed so that peeling off of the wiring member 81 from the cell can be suppressed even in a case where the uneven region 822 is not connected to the cell with any adhesive material interposed therebetween.

It is enough the length L of the uneven region 820 (822) along the x direction in the region 81a disposed on the back side of the first cell of the wiring member 81 is larger than 0. In a case where L is larger than 0, the first principal surface of the wiring member has unevenness over the entire region of the gap between the first cell 101 and the second cell 102, thus allowing the light utilizing efficiency of the module to be further improved. L may be 2 mm or more, 3 mm or more, or 4 mm or more, from the viewpoint of enhancing the cushioning action and adhesion with the encapsulant, with the uneven region of the wiring member disposed on the back surface of the first cell. On the other hand, L may be 20 mm or less, 10 mm or less, or 8 mm or less, from the viewpoint of sufficiently securing the electrical connection between the back electrode of the cell and the wiring member.

For the wiring member 81, along the y direction, the width W₂ of the uneven region 820 may be larger than the width W₁ of the flat region 810. As described above, the bent part 825 is formed in the uneven region 820 of the wiring member 81 in one or more embodiments. When the module undergoes a temperature change, the cell and the wiring member undergo a volume change. Since the cell and the wiring member are fixed with the adhesive materials 96 and 97 interposed therebetween, the distortion generated due to a difference in dimensional change between the cell and the wiring member tends to be concentrated on the wiring member located in the gap between the adjacent cells. In particular, the bent part of the wiring member is more likely to be cracked or fractured as compared with the other parts. When the width W₂ of the uneven region 820 is relatively large, strength of the bent part 825 is enhanced, so that the long-term reliability of the module against temperature changes and the like tend to be improved.

The method for manufacturing the wiring member with the flat region 810 and the uneven region 820 along the extending direction is not particularly limited. For example, as shown in FIG. 5, the wiring member 81 is obtained by cutting the wiring member 80 with flat regions 810 and uneven regions 820 alternately arranged along the extending direction, according to the cell size. In FIG. 5, the uneven region 820 is illustrated to be longer than the flat region 810. For the wiring member 80 before cutting, it is not always necessary for the length of the uneven region 820 to be larger than the length of the flat region 810, and the both regions may be equal in length, or the flat region may be larger in length. In cutting the wiring member 80 in accordance with the size of the cell, the cutting position may be adjusted such that the length of the uneven region 820 is larger than the length of the flat region 810 for the wiring member after the cutting.

The method for forming the uneven region and the flat region on the surface of the wiring member is not particularly limited. For example, a processed region where unevenness is formed by roller processing, press processing, etc., and a non-processed region where unevenness is not formed may be alternately arranged along the extending direction. Alternatively, after forming unevenness along the entire extending direction, the uneven shape may be crushed by press processing or the like to form a flat region.

A wiring member in which the width W₂ of the uneven region 820 is larger than the width W₁ of the flat region 810 can be easily obtained by forming unevenness by press processing in the uneven region and the flat region is remain unprocessed. In the press processing, unevenness is formed on the first principal surface by pressing from the first principal surface side, and the width W₁ of the processed region becomes larger than the width W₂ of the non-processed region.

When the unevenness is formed by pressing a roller while traveling the flat wiring member along the extending direction, unevenness is less likely to be formed at the start of pressing the roller. Thus, when an attempt is made to alternately form the uneven region and the flat region along the extending direction, the uneven shape of the uneven region may be ununiform or the unevenness height may be insufficient in the vicinity of the boundary between the uneven region and the flat region. In contrast, in the press processing, intermittent processing is carried out along the extending direction, thus allowing unevenness to be formed reliably even in the vicinity of the boundary. Furthermore, the pressing can easily form not only unevenness extending in parallel to the extending direction of the wiring member, but also unevenness extending at a predetermined angle with respect to the extending direction of the wiring member, and unevenness extending in a direction perpendicular to the extending direction of the wiring member.

When unevenness is formed by the press-processing, the width W₂ of the uneven region 820 becomes larger than the width W₁ of the flat region 810, and accordingly, the average thickness d₂ of the wiring member in the uneven region 820 is smaller than the thickness d₁ of the wiring member of the flat region 810. As shown in FIG. 3B, the thickness d₂ of the wiring member disposed on the light-receiving surface of the cell is small, thereby making it possible to secure the gap between the light-receiving-surface protection member 91 and the wiring member 81. In one or more embodiments, even in a case where the thickness of the encapsulant is small, sealing on the unevenness of the wiring member can be reliably carried out, and the reliability of the module can be thus improved. Furthermore, the small thickness of the encapsulant on the light-receiving side reduces the light absorption loss due to the encapsulant, thus leading to improved module performance.

In preparation of the module, first, a solar cell string 100 in which a plurality of cells are connected to each other via the wiring member is prepared. As mentioned above, the electrode of the cell and the wiring member 80 may be connected with a solder interposed therebetween. In this regard, the flat region of the first principal surface of the wiring member is connected to the back electrode 70 of the cell, and the second principal surface of the wiring member is connected to the light-receiving electrode 60 of the cell.

The solar cell string is sandwiched between the light-receiving-surface protection member 91 and the back-surface protection member 92 with the encapsulant 95 interposed, thereby forming a solar cell module. In one or more embodiments, a laminate in which the light-receiving surface encapsulant, the solar cell string, the back surface encapsulant and the back-surface protection member are placed in this order on the light-receiving-surface protection member is heated at predetermined conditions to cure the encapsulant. As described above, in a case where the uneven region 822 of the wiring member disposed on the back surface of the cell is not connected to the back electrode of the cell, the recessed part of the unevenness is filled with the encapsulant 95 getting around, thus contributing to the improved durability of the module by cushioning action and adhesion improvement action.

In one or more embodiments, the light-receiving-surface protection member 91 is light-transmissive, and glass, light-transmissive plastic or the like can be used. As the back-surface protection member 92, a resin film of polyethylene terephthalate (PET) or the like, or a laminated film having a structure in which an aluminum foil is sandwiched between resin films can be used. As the encapsulant 95, a transparent resin such as high-density polyethylene (HDPE), high-pressure low-density polyethylene (LDPE), linear low-density polyethylene (LLDPE), polypropylene (PP), ethylene/α-olefin copolymer, ethylene/vinyl acetate copolymer (EVA), ethylene/vinyl acetate/triallyl isocyanurate (EVAT), polyvinyl butyrate (PVB), silicon, urethane, acryl or epoxy may be used.

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

### DESCRIPTION OF REFERENCE CHARACTERS

50 photoelectric conversion section
60, 70 electrode
61, 71 finger electrode
62, 72 bus bar electrode
101 to 104 solar cell
80, 81, 82, 83 wiring member
810 flat region
820 uneven region
825 bent part
100 solar cell string
91, 92 protection member
95 encapsulant
96, 97 adhesive material (solder)
200 solar cell module

What is claimed is:

1. A solar cell module comprising:
a solar cell string comprising a first solar cell, a second solar cell, and a wiring member;
a light-receiving-surface protection member disposed on a light-receiving side of the solar cell string;
a back-surface protection member disposed on a back side of the solar cell string; and
an encapsulant that encapsulates the solar cell string between the light-receiving-surface protection member and the back-surface protection member,
wherein the light-receiving-surface protection member is light-transmissive,
wherein the first solar cell and the second solar cell are arranged apart from each other along a first direction and connected by the wiring member,
wherein the wiring member has a first principal surface and a second principal surface, and has a strip shape extending in the first direction,
wherein the first principal surface of the wiring member is connected to an electrode on a back surface of the first solar cell, and the second principal surface of the wiring member is connected to an electrode on a light-receiving surface of the second solar cell,
wherein, along the first direction, the wiring member has an uneven region and a flat region on the first principal surface,
wherein the uneven region is provided with unevenness, and the flat region is not provided with unevenness or is provided with unevenness that is smaller in height than the uneven region, and
wherein the uneven region extends from the light-receiving surface of the second solar cell to the back surface of the first solar cell.

2. The solar cell module according to claim 1, wherein the uneven region comprises triangular prism-shaped projected parts extending in parallel to each other on a surface of the wiring member.

3. The solar cell module according to claim 1, wherein a width of the uneven region in a second direction perpendicular to the first direction is larger than a width of the flat region in the second direction.

4. The solar cell module according to claim 2, wherein a width of the uneven region in a second direction perpendicular to the first direction is larger than a width of the flat region in the second direction.

5. The solar cell module according to claim 1, wherein the electrode on the back surface of the first solar cell and the flat region of the wiring member are connected with a solder interposed therebetween.

6. The solar cell module according to claim 2, wherein the electrode on the back surface of the first solar cell and the flat region of the wiring member are connected with a solder interposed therebetween.

7. The solar cell module according to claim 3, wherein the electrode on the back surface of the first solar cell and the flat region of the wiring member are connected with a solder interposed therebetween.

8. The solar cell module according to claim 4, wherein the electrode on the back surface of the first solar cell and the flat region of the wiring member are connected with a solder interposed therebetween.
